(19) United States
(12) Patent Application Publication
(10) Pub. No.: US 2007/0012422 A1
(43) Pub. Date: Jan. 18, 2007

(54) Heat radiating fin

(76) Inventor: Tsung Hsien Huang, Lujhou City (TW)

Correspondence Address: PRO-TECHTOR INTERNATIONAL SERVICES, 20775 NORADA CT., SARATOGA, CA, 95070, US

(21) Appl. No.: 11/182,253

(22) Filed: Jul. 14, 2005

(51) Int. Cl. H05K 7/20

(52) U.S. Cl. 165/80.3; 361/704

(57) ABSTRACT

The present invention provides a type of heat radiating fin, particularly one having multiple-face jutted snaps, said multiple-face jutted snaps are snapped to and pulled through matching snap holes provided on matching snap fold sides on the same heat-radiating fin, thereby to enhance high heat-radiating efficiency.

### BACKGROUND OF THE INVENTION

The heat-radiating efficiency of hot points of all precision electronic or electrical products or assemblies is facing the problem of limited peripheral space. Take the example of a computer set, when the computer is started, the central processing unit produces high heat and enters into a state of instability, resulting in crashing of the system or even burning of the central processing unit. The high heat is produced mainly due to the executing speed of the central processing unit. Generally speaking, the higher the executing speed of the central processing unit, the higher heat will be produced by the central processing unit. Therefore, we have to rely on the use of a heat-radiating device to reduce the temperature of the central processing unit, in order to maintain normal operation. At the present, most computers are using configured type of heat radiating fins to reduce the temperature of central processing unit. Though there are a wide variety of configurations in the conventional heat-radiating fins, they are restricted by the limited space around the central processing unit. Therefore, even with the increase of the number or total area of the heat radiating fins, no significance increase can be gained in their radiating efficiency. Theoretically, however, turbulence can be employed to enhance heat-radiating efficiency.

In view of the above, the present invention provides a type of heat radiating fin, relating to a multilateral heat radiating fin main unit, on its periphery being a specified number of snap fold sides, each snap fold side having at least one snap hole, at the front part of each snap hole being a multiple-face jutted snap, said multiple-face jutted snap being snapped to and pulled out of matching snap hole provided on matching snap fold side on the same heat radiating fin, forming multiple-face turbulence juts to transmit the high heat produced by various precision electronic or electric products or assemblies to the inside walls of assembled heat radiating fins, thereby forming turbulence hot air before it is discharged, to enhance heat radiating efficiency.

### SUMMARY OF THE INVENTION

The primary objective of the present invention is to provide a type of heat-radiating fin having a specified number of multiple-face jutted snaps to enhance heat-radiating efficiency.

Another objective of the present invention is to provide a type of heat-radiating fin comprising of a specified number of multiple-face jutted snaps, said jutted snaps are snapped to and pulled out of matching snap holes provided on matching snap fold sides on the same heat-radiating fin, thereby forming a specified number of multiple-face turbulence juts with turbulence performance.

The additional objective of this invention is to offer an array.

### BRIEF DESCRIPTION OF THE DRAWINGS

FIG. 1: A perspective view of a preferred embodiment of the present invention of heat radiating fin 1.

FIG. 2: A perspective blowup of a U-shape jutted snap 113 in FIG. 1.

FIG. 3: An assembled view of heat radiating fin 1,2 in a preferred embodiment of the present invention.

FIG. 4: A perspective view of the process of a multiple-face jutted snap 113 provided on a snap fold side 11 of the heat-radiating fin 1, as shown in FIG. 3, being snapped to a matching snap hole 211 provided on a matching fold side 21 of the assembled matching heat-radiating fin 2.

FIG. 5: An assembled view of the multiple-face jutted snap 113 provided on a snap fold side 11 of the heat-radiating fin 1, as shown in FIG. 3, being snapped to a matching snap hole 211 provided on a matching fold side 21 of the assembled matching heat-radiating fin 2.

FIG. 6: An assembled view of a specified number of heat-radiating fins in the preferred embodiment of the present invention.

FIG. 7: A section view of a specified number of heat-radiating fins in the preferred embodiment of the present invention.

### DETAILED DESCRIPTION OF PREFERRED EMBODIMENTS

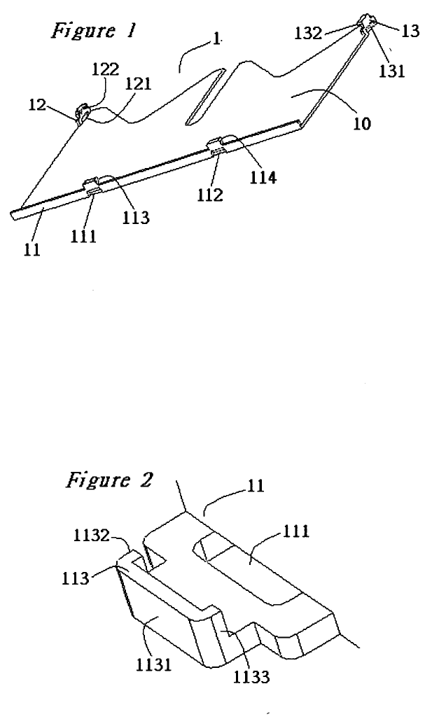

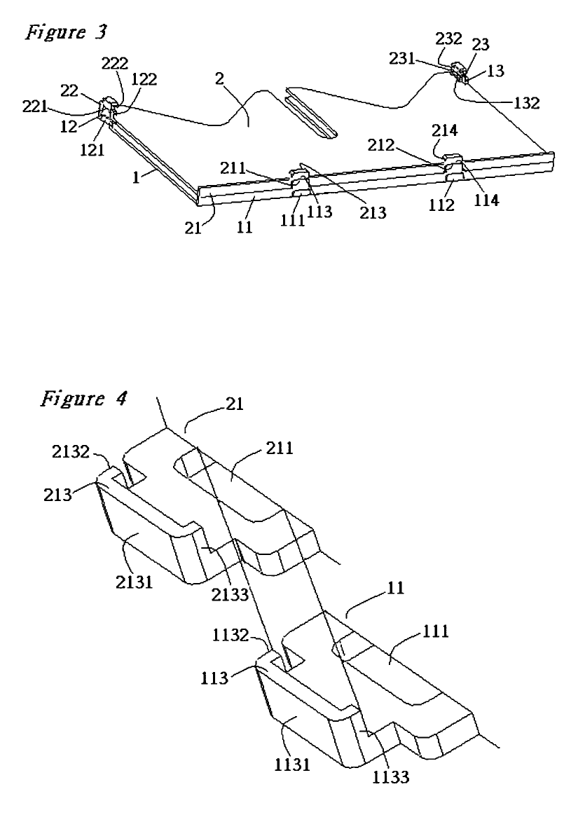

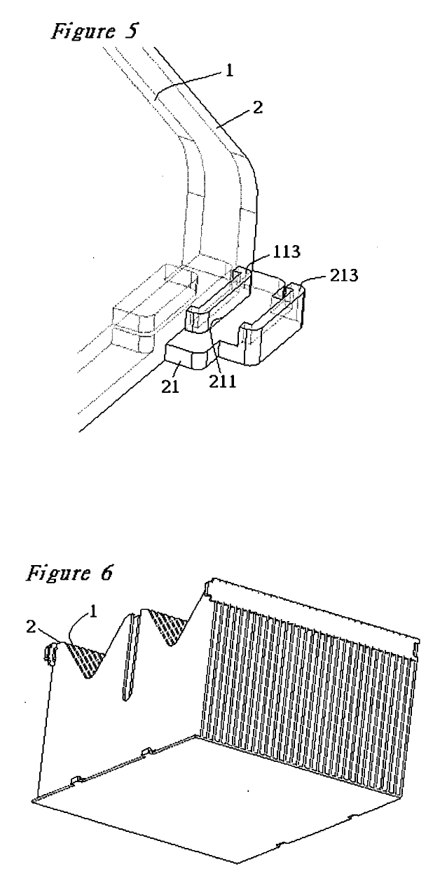

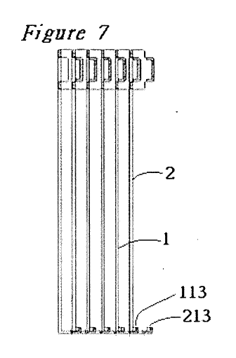

As shown in FIG. 1, on the bottom, left and right sides of the multilateral heat-radiating fin main unit 10 are respectively provided with a snap fold side 11,12,13. The snap fold side 11,12,13 is respectively bent vertically in 90 degrees to a same side of the multilateral heat-radiating fin main unit 10. Wherein, on the snap fold side 11 on the bottom side of the multilateral heat-radiating fin main unit 10 are provided with two snap holes 111,112. On the front of the snap holes 11,112 is respectively provided a U-shape jutted snap 113,114 that is bent vertically in 90 degrees to the snap fold side 11. Wherein, on a fold side 12 on the left of the multilateral heat-radiating fin main unit 10 is provided a snap hole 121. On the front of the snap hole 121 is a U-shape jutted snap 122 that is bent vertically in 90 degrees to the snap fold side 12. Wherein, on a fold side 13 on the right bottom side of the multilateral heat-radiating fin main unit 10 is provided a snap hole 131. On the front of the snap hole 131 is provided a U-shape jutted snap 132 that is bent vertically in 90 degrees to the snap fold side 13. Wherein, the bottom side of the multilateral heat-radiating fin main unit 10 and the snap fold sides 11,12,13 on left and right are respectively bent vertically in 90 degrees to a same side of the multilateral heat-radiating fin main unit 10. The snap holes 111,112 on the snap fold side 11 have exactly the same shape as the snap hole 121 on the snap fold side 12 and the snap hole 131 on the snap fold side 13. The snap holes 111,112 on the snap fold side 11 have exactly the same shape as the U-shape snap jutted snap 113,114 that are bent vertically in 90 degrees to the snap fold side 11, the U-shape jutted snap 122 provided at the front of the snap hole 121 of the snap fold side 12 and bent vertically in 90 degrees to the snap fold side 12, and the U-shape jutted snap 132 provided at the front of the snap hole 131 of the snap fold side 13 and bent vertically in 90 degrees to the snap fold side 13, and are respectively parallel to the multilateral heat-radiating fin main unit 10. As shown in FIG. 2, there are three walls 1131,1132, 1133 on the U-shape jutted snap 113 that is bent vertically in 90 degrees to the snap fold side 11 at the front of the snap hole 111 of the snap fold side 11. As shown in FIGS. 3 to 5, the heat-radiating fins 1,2 have exactly the same shape. The U-shape jutted snaps 113,114 of the heat-radiating fin 1 provided on the front part of the snap holes 111,112 of the snap fold side 11, and the U-shape jutted snap 122 provided on the front part of the snap hole 121 of the snap fold side 12, and the U-shape jutted snap 132 on the front part of the snap hole 131 of the snap fold side 13 are respectively snapped into and properly pulled through matching snap holes 211,212 on the snap fold side 21, matching snap hole 221 on the snap fold side 22, and matching snap hole 231 on the snap fold side 23, forming a multiple-faced turbulence jut; as shown in FIGS. 1 through 7, when convection cold air flows into the bottom, left and right sides between the multilateral heat-radiating fin main units 10,20 with multiple heat-radiating fins 1,2 inter-hooked to each other, the cold air is obstructed by a specified number of multiple-faced turbulence juts formed by U-shape jutted snaps 113,114,122,132 respectively comprising of matching snap holes 211,212 being provided on the snap fold side 21 and snapped into and properly pulled out of the heat-radiating fin 2, and matching snap hole 221 provided on the snap fold side 22, and matching snap hole 231 on the snap fold side 23. Thereby, turbulence hot air is formed and discharged out of the computer set, to enhance heat-radiating efficiency.

As described above, the present invention provides a type of heat-radiating fins comprising of a specified number of multiple-faced juts. The multiple-faced juts are snapped into and pulled out of a same number of matching snap holes provided on matching snap fold sides, forming a specified number of multiple-faced turbulence juts to transmit the high heat produced by all types of precision electronic or electrical products or assemblies to the inside walls of assembled heat-radiating fins, forming turbulence hot air for discharge, to enhance heat-radiating efficiency.

It is to be understood that the above description covering some examples of preferred embodiment of the present invention should not be based to restrict or limit the present invention, and that all variations, modification and applications made without departing the import of the present invention shall be included in the subject claim, including but not limited to reconfiguration of the U-shape jutted snaps 113,114,122,132,213,214,222,232 to jutted snaps of two-face shape, four-face shape, or cylindrical shape or other multiple-face geological shapes, to the effect the said jutted snaps can be snap joined and pulled through matching snap holes provided on matching snap fold sides of the same heat-radiating fin to form turbulence juts.

What is claimed is:

1. A type of heat-radiating fin, comprising of multilateral heat-radiating fin main unit having on a periphery thereof a specified number of snap fold sides, each snap fold side having at least one snap hole, at a front part of each snap hole being a multiple-face jutted snap.

2. The heat radiating fin of claim 1, wherein the multiple-face jutted snap is configured to have at least two faces, including three faces, four faces, a cylindrical shape, and other multiple-face geological shapes.

3. The heat radiating fin of claim 1, wherein the multiple-face jutted snap is snap joined and pulled through matching snap holes provided on matching snap fold sides on a same shape of heat-radiating fin, thereby forming a multiple-face turbulence jut.

4. The heat radiating fin of claim 2, wherein the multiple-face jutted snap is snap joined and pulled through matching snap holes provided on matching snap fold sides on a same shape of heat-radiating fin, thereby forming a multiple-face turbulence jut.
